(19) United States
(12) Patent Application Publication
(10) Pub. No.: US 2018/0066363 A1
(43) Pub. Date: Mar. 8, 2018

(54) VORTICAL ATOMIZING NOZZLE ASSEMBLY, VAPORIZER, AND RELATED METHODS FOR SUBSTRATE PROCESSING SYSTEMS

(71) Applicant: Tokyo Electron Limited, Tokyo (JP)

(72) Inventors: Ronald Nasman, Averill Park, NY (US); Danny Newman, Clifton Park, NY (US); Rodney L. Robison, East Berne, NY (US)

(21) Appl. No.: 15/601,372

(22) Filed: May 22, 2017

Related U.S. Application Data
(60) Provisional application No. 62/384,825, filed on Sep. 8, 2016.

(51) Int. Cl. C23C 16/455; B01F 3/04; C23C 16/448; C23C 18/16

(52) U.S. Cl. CPC C23C 16/45563; B01F 3/04; C23C 16/448; Y10T 137/2104; C23C 18/1644; Y10T 137/2098; C23C 16/45514

(57) ABSTRACT

A vortical atomizing nozzle assembly, vaporizer, and related methods are disclosed for substrate processing systems. The vaporizer introduces an atomized or vaporized liquid into a substrate processing system and includes a vaporizer chamber, a nozzle assembly coupled to the inlet for the vaporizer chamber, and a carrier gas channel coupled to the nozzle assembly. The nozzle assembly includes a premix chamber, an outlet channel, and an expanding nozzle. The premix chamber includes a liquid inlet to receive the liquid to be vaporized and a gas inlet to receive the carrier gas. The carrier gas channel is positioned with respect to the gas inlet to cause a vortical flow within the premix chamber upon introduction of the carrier gas through the carrier gas channel. The premixed liquid from the premix chamber is received by the outlet channel and exits the outlet channel into the expanding nozzle.

### RELATED APPLICATIONS

This application claims priority to the following co-pending provisional application: U.S. Provisional Patent Application Ser. No. 62/384,825, filed Sep. 8, 2016, and entitled “VORTICAL ATOMIZING NOZZLE AND VAPORIZER AND METHOD OF USING,” which is hereby incorporated by reference in its entirety.

### BACKGROUND

The present disclosure relates to semiconductor process integration techniques and, more particular, to methods and systems that vaporize fluids for substrate processing systems and methods.

Semiconductor device formation involves a series of manufacturing techniques related to the formation, patterning and removal of a number of layers of material on a substrate. Many semiconductor processes, such as atomic layer deposition (ALD) processes, chemical vapor deposition (CVD) processes, and certain etch processes, have improved results by employing liquid vaporization as a technique to deliver process chemicals in gas form to reactor chambers. Rather than heating solid materials with a carrier gas to induce sublimation of the solid materials, liquid vaporization systems apply heat only at the point of use thereby preventing or significantly reducing decomposition of certain process chemicals or materials that tend to decompose if kept at elevated temperatures.

While some process chemicals can easily be vaporized, other process chemicals pose significant obstacles for use in liquid vaporization systems. For example, chemicals that have a high viscosity may need to be mixed with a solvent in order to flow through the generally small supply tubes and orifices of the vaporizer equipment. In such cases, the solvent can selectively vaporize and leave behind a cooled mixture of increasing concentration that can eventually lead to clogging within the vaporizer equipment. Other chemicals may demonstrate instability and have an increasing tendency to breakdown relative to increasing temperature, and the byproducts of this breakdown can leave deposits in supply lines and orifices of the vaporizer equipment that also lead to clogging within the vaporizer equipment. In addition, a liquid chemical to be vaporized can contain impurities that are left behind when the chemical is vaporized, and resulting deposits can also lead to clogging within the vaporizer equipment. Other factors and causes can also lead to clogging within vaporizer equipment, and clogging can also occur from combinations of different causes.

Clogging within a vaporizer can also prove to be extremely difficult to resolve and may require component replacement or time consuming cleaning operations. For example, when vaporizer equipment uses complex flow paths through small-size fluid channels, clogs can be very difficult or practically impossible to remove through cleaning operations. Replacement of vaporizer components then becomes the only practical solution but generally at great cost to the user of the vaporizer equipment.

### SUMMARY

A vortical atomizing nozzle assembly, vaporizer, and related methods are disclosed for substrate processing systems. For the disclosed embodiments, the vaporizer introduces an atomized or vaporized liquid into a substrate processing system while improving performance and reliability. The vaporizer includes a vaporizer chamber, a nozzle assembly coupled to the inlet for the vaporizer chamber, and a carrier gas channel coupled to the nozzle assembly. The nozzle assembly includes a premix chamber, an outlet channel, and an expanding nozzle. The premix chamber includes a liquid inlet to receive the liquid to be vaporized and a gas inlet to receive the carrier gas. The carrier gas channel is positioned with respect to the gas inlet for the premix chamber to cause a vortical flow within the premix chamber upon introduction of the carrier gas through the carrier gas channel. The vortical flow reduces the build-up of residue within the liquid inlet and the gas inlet for the premix chamber thereby improving performance and reliability. The premixed liquid from the premix chamber is received by the outlet channel and exits the outlet channel into the expanding nozzle. Additional features and variations can be implemented, if desired, and related systems and methods can be utilized, as well.

For one embodiment, a vaporizer is disclosed to introduce a vaporized liquid into a substrate processing system including a vaporizer chamber having an inlet, a nozzle assembly coupled to the inlet for the vaporizer chamber, and a carrier gas channel. The nozzle assembly includes a premix chamber having a liquid inlet to receive a liquid to be vaporized and a gas inlet to receive a carrier gas, an outlet channel to receive a premixed liquid from the premix chamber, and an expanding nozzle coupled to the outlet channel. The carrier gas channel is coupled to the gas inlet for the premix chamber and positioned with respect to the gas inlet to cause a vortical flow within the premix chamber upon introduction of the carrier gas through the carrier gas channel.

In additional embodiments, the premix chamber includes a cylindrical region including the liquid inlet and a conical region adjacent the outlet channel. In further embodiments, the conical region includes a contracting cone configured to increase a speed for the premixed liquid leaving the premix chamber. In further embodiments, the expanding nozzle includes an expanding cone configured to facilitate vaporization of the premixed liquid.

In additional embodiments, the carrier gas channel is positioned to introduce the carrier gas into the premix chamber in a direction tangential to the interior wall of the premix chamber. In further embodiments, In further embodiments, the carrier gas channel has multiple regions with different diameters including a first region coupled to a source for the carrier gas and a second region coupled to the gas inlet for the premix chamber where the second region has a smaller diameter than the first region.

In additional embodiments, the vaporizer further includes a metal fitting positioned to introduce the liquid through the liquid inlet for the premix chamber. In further embodiments, the vaporizer includes a metal gasket within the metal fitting, and the metal gasket has an orifice configured to introduce the liquid through the liquid inlet for the premix chamber. In further embodiments, the metal fitting includes a receptacle having one or more access ports configured to allow the metal gasket to be accessed and removed. In still further embodiments, the nozzle assembly is formed as part of a metal flange coupled to the metal fitting. In further embodiments, the vaporizer includes a threaded receptacle welded to the metal flange where the threaded receptacle being configured to receive a metal nut for the metal fitting. In still further embodiments, the metal fitting, the metal flange, and the threaded receptacle provide metal-to-metal vacuum seals.

In additional embodiments, the outlet channel is sized to generate backpressure within the premix chamber. In further embodiments, the backpressure is configured to reduce early vaporization within the premix chamber and to reduce residue build-up within the liquid inlet and the gas inlet.

In additional embodiments, the nozzle assembly is configured to achieve a target residence time for the liquid within the premix chamber prior. In further embodiments, the target residence time is configured to reduce early vaporization within the premix chamber and to reduce residue build-up within the liquid inlet and the gas inlet.

In additional embodiments, the vortical flow is configured to cause a sweeping action for the carrier gas within the premix chamber. In further embodiments, the sweeping action is configured to reduce residue build-up within the premix chamber.

In additional embodiments, the vaporizer includes at least one porous foam member arranged within the vaporizer chamber between the inlet for the vaporizer chamber and an outlet for the vaporizer chamber. In further embodiments, the at least one porous foam member includes an aluminum foam.

For one embodiment, a method is disclosed to introduce a vaporized liquid into a substrate processing system using a vaporizer chamber and a nozzle assembly coupled to the vaporizer chamber. The method includes introducing a liquid into a premix chamber for the nozzle assembly through a liquid inlet for the premix chamber where the nozzle assembly also includes an outlet channel coupled to the premix chamber and an expanding nozzle coupled to the outlet channel. While introducing the liquid into the premix chamber, the method also includes introducing a carrier gas into the premix chamber through a gas inlet for the premix chamber to generate a premixed liquid. The method further includes passing the premixed liquid from the premix chamber through the outlet channel and the expanding nozzle to facilitate vaporization of the premixed liquid and injecting the premixed liquid from expanding nozzle into the vaporizer chamber through an inlet for the vaporizer chamber. For the method, the carrier gas is introduced through the gas inlet for the premix chamber using a carrier gas channel positioned with respect to the gas inlet for the premix chamber to cause a vortical flow within the premix chamber.

In additional embodiments, the premix chamber includes a cylindrical region including the liquid inlet and a conical region adjacent the outlet channel. In further embodiments, a speed of the premixed liquid is increased by a contracting cone within the conical region as the premixed liquid flows into the outlet channel. In further embodiments, the method includes facilitating vaporization of the premixed liquid using an expanding cone for the expanding nozzle.

In additional embodiments, the method includes introducing the carrier gas into the premix chamber in a direction tangential to the interior wall of the premix chamber. In further embodiments, the carrier gas channel has multiple regions with different diameters including a first region coupled to a source for the carrier gas and a second region coupled to the gas inlet for the premix chamber where the second region has a smaller diameter than the first region.

In additional embodiments, the liquid is introduced through the liquid inlet for the premix chamber using a metal fitting. In further embodiments, a metal gasket is included within the metal fitting, and the method further includes using an orifice within the metal gasket to introduce the liquid through the liquid inlet for the premix chamber. In further embodiments, the metal fitting includes a receptacle having one or more access ports, and the method further includes accessing and removing the metal gasket through the one or more access ports. In still further embodiments, the nozzle assembly is formed as part of a metal flange coupled to the metal fitting. In further embodiments, the method includes receiving a metal nut within a threaded receptacle welded to the metal flange.

In additional embodiments, the method includes providing metal-to-metal vacuum seals using the metal fitting, the metal flange, and the threaded receptacle. In further embodiments, the method includes generating backpressure within the premix chamber using the outlet channel. In still further embodiments, the method includes using the backpressure to reduce early vaporization within the premix chamber and to reduce residue build-up within the liquid inlet and the gas inlet.

In additional embodiments, the method includes configuring the nozzle assembly to achieve a target residence time for the liquid within the premix chamber. In further embodiments, the method includes using the target residence time to reduce early vaporization within the premix chamber and to reduce residue build-up within the liquid inlet and the gas inlet.

In additional embodiments, the method includes using the vortical flow to cause a sweeping action for the carrier gas within the premix chamber. In further embodiments, the method includes using the sweeping action to reduce residue build-up within the premix chamber.

In additional embodiments, the method includes passing the premixed liquid from the expanding nozzle through at least one porous foam member arranged within the vaporizer chamber between the inlet for the vaporizer chamber and an outlet for the vaporizer chamber. In further embodiments, the at least one porous foam member includes an aluminum foam.

Different or additional features, variations, and embodiments can be implemented, if desired, and related systems and methods can be utilized, as well.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a cross-section perspective diagram of an example embodiment for a nozzle assembly including a premix chamber, an outlet channel, and an expanding nozzle as well as a carrier gas channel that generates a vortical flow within the premix chamber.

FIG. 1B is a perspective diagram of an example embodiment showing an access port to a metal gasket through which liquid is introduced into the premix chamber for the nozzle assembly.

FIG. 2 is a cross-section view diagram of the metal flange that cuts through the carrier gas channel and the premix chamber for the nozzle assembly.

FIG. 3 is a representative perspective view diagram for vortical flow within the premix chamber and passage of the premixed liquid into the outlet channel and the expanding nozzle.

FIG. 4 is a cross-section diagram of an example embodiment where the nozzle assembly described herein is used within a full vaporizer.

FIG. 5 is a process diagram of an example embodiment for using a nozzle assembly as described herein for vaporization within a substrate processing system.

FIG. 6 illustrates a deposition system that uses a vaporizer to deposit a thin film, such as a conductive film, a non-conductive film, or a semi-conductive film.

### DETAILED DESCRIPTION

A vortical atomizing nozzle assembly, vaporizer, and related methods are disclosed for substrate processing systems. For the disclosed embodiments, the vaporizer introduces an atomized or vaporized liquid into a substrate processing system while improving performance and reliability. The vaporizer includes a vaporizer chamber, a nozzle assembly coupled to the inlet for the vaporizer chamber, and a carrier gas channel coupled to the nozzle assembly. The nozzle assembly includes a premix chamber, an outlet channel, and an expanding nozzle. The premix chamber includes a liquid inlet to receive the liquid to be vaporized and a gas inlet to receive the carrier gas. The carrier gas channel is positioned with respect to the gas inlet for the premix chamber to cause a vortical flow within the premix chamber upon introduction of the carrier gas through the carrier gas channel. The vortical flow reduces the build-up of residue within the liquid inlet and the gas inlet for the premix chamber thereby improving performance and reliability. The premixed liquid from the premix chamber is received by the outlet channel and exits the outlet channel into the expanding nozzle. Additional features and variations can be implemented, if desired, and related systems and methods can be utilized, as well.

The disclosed embodiments address problems in prior solutions by reducing the potential for clogging within vaporizer equipment and thereby improving tool up time. Further, the disclosed embodiments simplify nozzle repair if clogging does occur thereby reducing cost of ownership. More particularly, the disclosed embodiments include a nozzle assembly that premixes a liquid to be vaporized with a carrier gas behind an atomizing orifice and expanding nozzle. The carrier gas is introduced into the small volume of the premix chamber eccentrically so as to generate a strong vortex within the premix chamber. This vortical flow reduces residue build-up within the premix chamber thereby improving performance and reliability. A variety of embodiments can be implemented while still taking advantage of the nozzle assembly and vortical premix techniques described herein.

The top of the premix chamber is preferably sealed. For example, the top of the premix chamber can be sealed using a metal fitting (e.g., ⅛″ VCR® (Vacuum Coupling Radiation) fitting available from Swagelok Company) that includes a metal gasket (e.g., VCR® gasket). The metal gasket sealing the top of the chamber includes a small orifice or group of holes through which the liquid is introduced into the premix chamber. This orifice, group of holes, and/or other opening(s) can also be customized or configured based upon the liquid being introduced into the premix chamber in order to obtain optimal flow control, to limit vaporization upstream of the line when not desired, and/or to achieve other desired objectives for the system.

The bottom of the premix chamber preferably includes an expanding nozzle that helps to atomize or vaporize the premixed liquid. The backpressure behind the expanding nozzle and the outlet channel for the premix chamber reduces early evaporation in the premix chamber, lowering the risk for residue build up. Because the premix chamber is small, and the velocities high, the target residence time is low for the mixture within the premix chamber. Additionally, the premix chamber is not required to be heated and may also be cooled for some embodiments to further aid in limiting evaporation and residue build up. In addition, the increased velocities of the imposed vortical flow helps to ensure that the walls of the chamber are swept clean of any build up as liquid and residue are discouraged from occurring on the surface in the presence of such strong vortical gas flows. The gas inlet is not expected to clog due to the strong incoming flows that reduce the likelihood of liquid exposure and residue build up. If the liquid orifice should at some time clog, however, the problem can be quickly resolved by replacing the metal gasket that includes the orifice, minimizing downtime as compared to prior solutions where clogging typically occurs in locations difficult to access and/or replace.

In operation as described in more detail below, the liquid is introduced at the top of the premix chamber within which the vortex is being generated. As the drops of liquid are forced into the premix chamber, the liquid is exposed to the sweeping action provided by the shearing effects of the high-speed vortical flows from the gas being introduced into the premix chamber. As the fluid is drawn down toward the outlet channel, the gas speed is increased by the contracting diameter of a bottom contracting conical region of the premix chamber. The fluid is forced to the outer wall by centrifugal force and accelerates toward the outlet channel. In the outlet channel, the premixed liquid (e.g., mixture of liquid to be vaporized and carrier gas) are accelerated by the pressure difference between the premix chamber and the vaporization chamber. The added mass flow of the liquid and expansion induced by vaporization in the premix chamber increases the backpressure over just providing a carrier gas flow alone. By interaction with the wall and shearing force of the accelerated gas within the outlet channel, the liquid is extended and stretched as it moves towards the nozzle exit. The premixed liquid exits the expanding nozzle through the atomizing outlet channel at a high rate of speed, discouraging the possibility of residue build up. Smaller atomized droplets form as the premixed liquid exits the outlet channel into the expanding nozzle. The passage diameter of the expanding nozzle then slowly expands into an open nozzle allowing for an atomized spray to enter the vaporization chamber. As described further below, aluminum foam, which can be heated for some embodiments, can also be included within the vaporization chamber to further facilitate and improve the vaporization process.

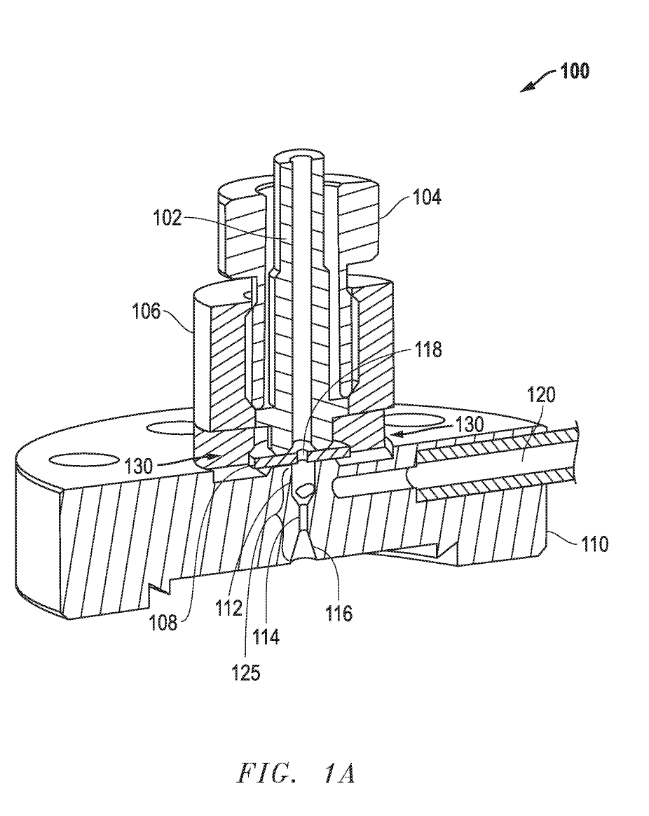

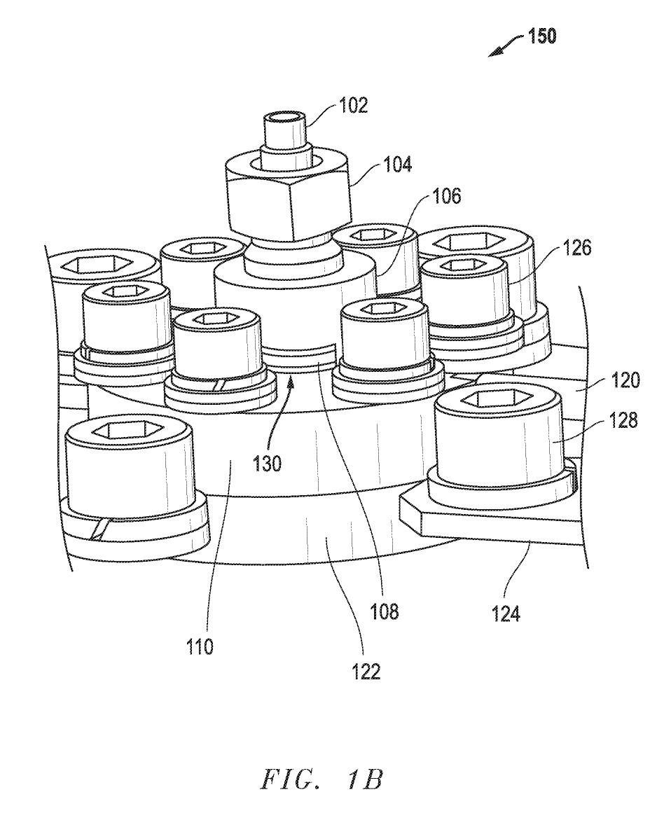

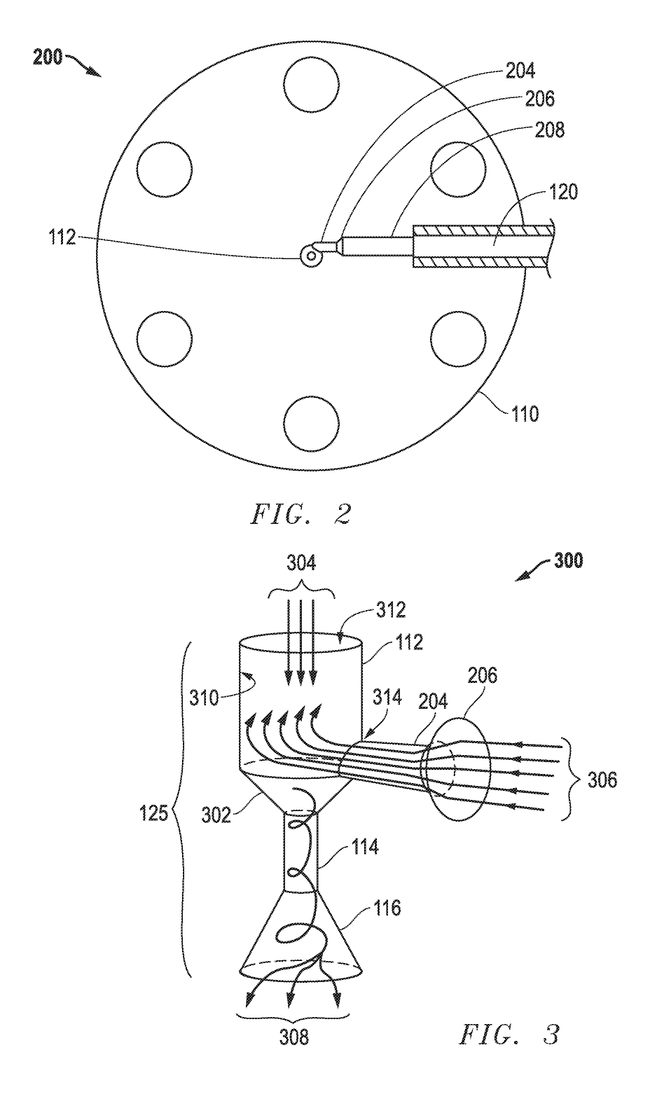

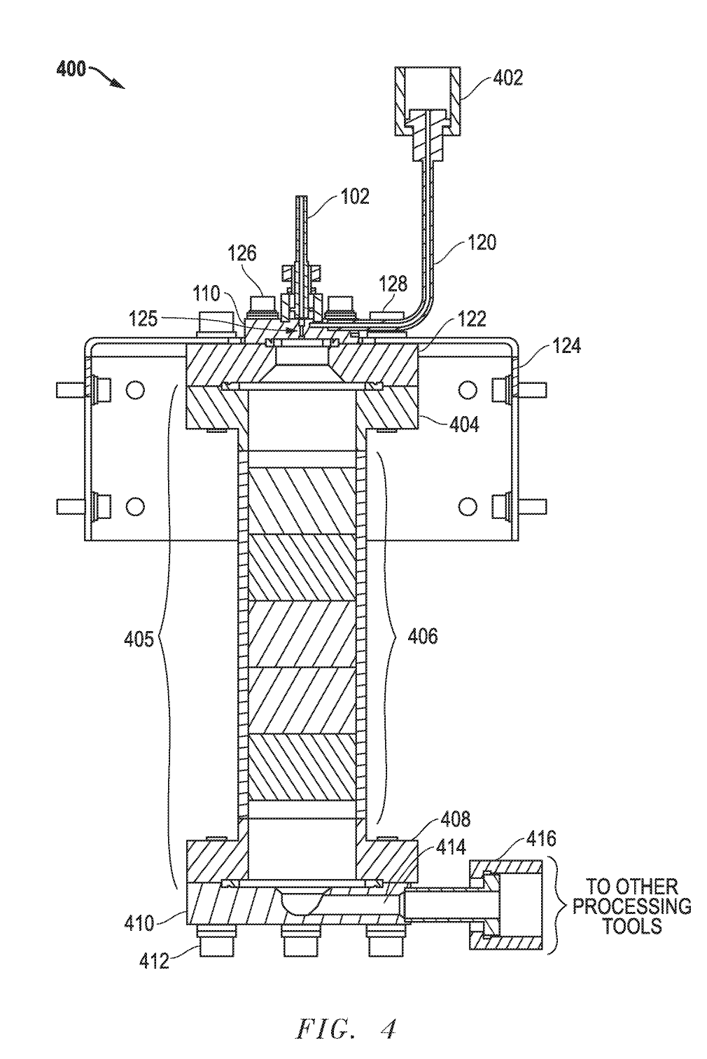

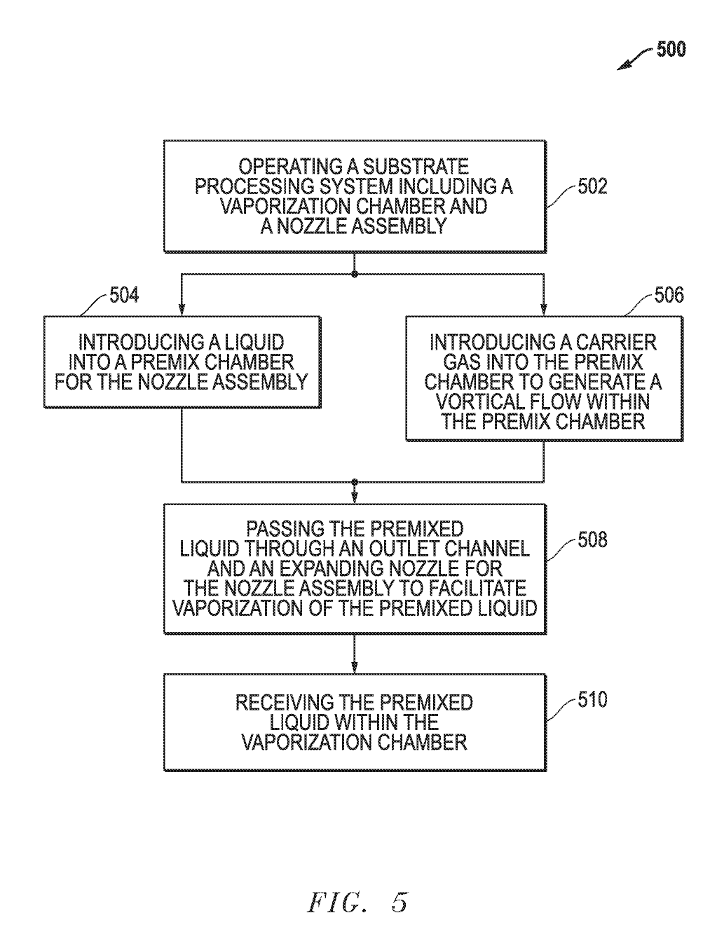

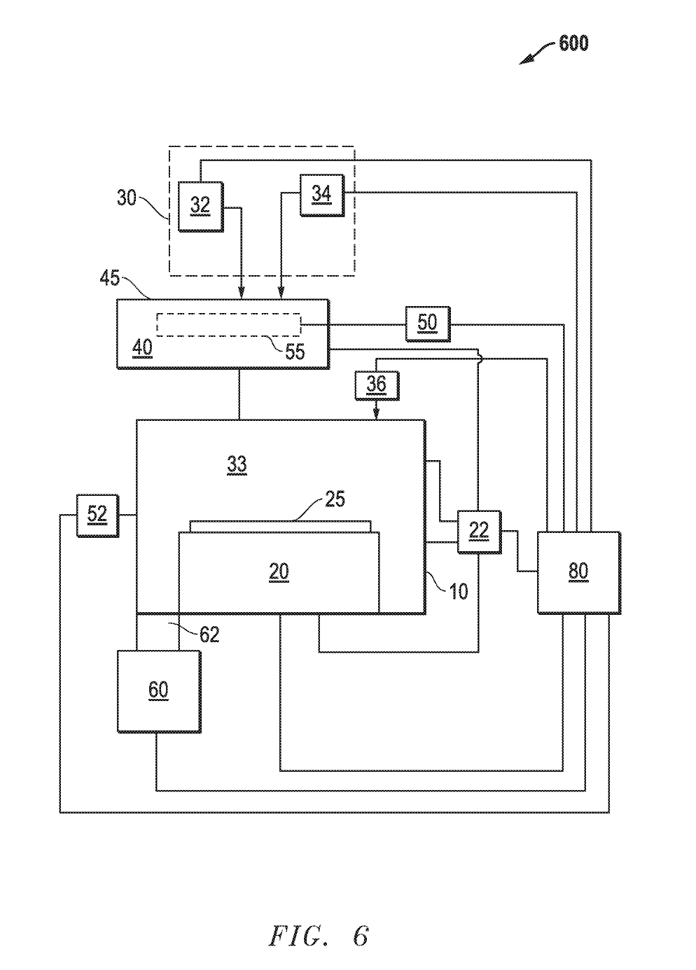

Embodiments for the vortical atomizing nozzle assembly and related vaporizer are now described in more detail with respect to the drawings. FIG. 1A provides a cross-section perspective diagram of a nozzle assembly along with a carrier gas channel that generates a strong vortical flow within a premix chamber for the nozzle assembly. FIG. 1B provides a perspective diagram of an access slot to a metal gasket through which the liquid enters the premix chamber for the nozzle assembly. FIG. 2 is a cross-section view diagram of the metal flange that cuts through the carrier gas channel and the nozzle assembly. FIG. 3 is a representative perspective view diagram for the vortical flow within the premix chamber. FIG. 4 is a cross-section diagram of the nozzle assembly used within a full vaporizer for a substrate processing system. FIG. 5 is a process diagram for a method to introduce an atomized or vaporized liquid into a substrate processing system using the nozzle assembly described herein. FIG. 6 is a block diagram that illustrates a deposition system that uses a vaporizer to deposit a thin film, such as a conductive film, a non-conductive film, or a semi-conductive film. Variations and further embodiments can also be implemented while still taking advantage of the nozzle assembly and vortical premix techniques described herein.

Now looking to FIG. 1A, a cross-section perspective diagram is shown for an example embodiment 100 including a nozzle assembly 125 having a premix chamber 112, an outlet channel 114, and an expanding nozzle 116. The liquid to be vaporized enters the premix chamber 112 through a gland 102 and a metal gasket 108 positioned above the premix chamber 112. The metal gasket 108 includes an orifice 118 through which the liquid enters the premix chamber 112. A threaded receptacle 106 is threaded to receive a metal nut 104 as part of a metal fitting, and for certain embodiments this threaded receptacle 106 can be welded to a metal flange 110 (e.g., a CONFLAT® (CF) flange available from Varian, Inc.). Access ports 130 are located on each side of the threaded receptacle 106 to provide access to the metal gasket 108. The access ports 130 allow for easy access to the metal gasket 108 should deposits occur that bind the metal gasket 108 to the metal flange 110. For example, if binding should occur between the metal gasket 108 and the metal flange 110, a non-marring tool can be inserted through the access ports 130 to pry and release the metal gasket 108 so that the seal surfaces can be cleaned. If cleaning is not adequate, the metal gasket 108 can be easily replaced through the access ports 130, which are sized to allow for the metal gasket 108 to be inserted into place. It is also noted that only one access port 130 could be provided, if desired, and additional access ports 130 could also be provided. Further, certain embodiments could eliminate the access ports 130 while still taking advantage of the nozzle assembly and vortical premix techniques described herein.

In operation, the carrier gas enters the premix chamber 112 through a carrier gas channel 120. The premix chamber 112 is cylindrical with a conical bottom that leads to an outlet channel 114 for the premix chamber 112. As described further herein, the carrier gas channel 120 is aligned, positioned, and oriented with respect to the interior of the premix chamber 112 so as to generate strong vortical flows within the premix chamber 112 that reduce residue build-up and facilitate vaporization of the liquid entering through the gland 102 and orifice 118. The premixed liquid (e.g., mixture of vaporized liquid and carrier gas) then exits the premix chamber 112 through outlet channel 114, and the outlet channel 114 in turn passes the premixed liquid to the expanding nozzle 116. The expanding nozzle 116 facilitates further vaporization of the premixed liquid.

FIG. 1B is a perspective diagram of an example embodiment 150 showing the access port 130 to the metal gasket 108 through which liquid is introduced into the premix chamber 112 for the nozzle assembly 125. The carrier gas channel 120 is also shown entering the metal flange 110 for this embodiment. As indicated above, the threaded receptacle 106, which includes the access port 130, can be welded to a metal flange 110. As shown in FIG. 1A, an additional access port 130 can also be provided on the opposite side of the threaded receptacle 106. The metal flange 110 can further be coupled to an additional metal flange 122, and bolts 126 are used to clamp the metal flange 110 to an additional metal flange 122. As shown with respect to embodiment 400 in FIG. 4 below, the additional metal flange 122 is further clamped to a mounting bracket 124 and to the top metal flange 404 for the vaporizer core 405 using bolts 128.

As indicated above, if binding should occur between the metal gasket 108 and the metal flange 110, a non-marring tool can be inserted through the access port 130 to pry and release the metal gasket 108. Preferably, multiple access ports 130 are provided, for example on opposite sides of the threaded receptacle 106 so that multiple sides of the metal gasket 108 can be reached and released with the non-marring tool. Once released, the metal gasket 108 can be removed, and the seal surfaces can be cleaned. If cleaning is not adequate, the metal gasket 108 can be removed and easily replaced with a new metal gasket 108 through the access ports 130, which are sized to allow for the metal gasket 108 to be removed and/or inserted into place. It is also noted that the metal gasket 108 can also be removed and replaced through the one or more access ports 130 if a different sized orifice 118 as is desired for the liquid being introduced through the gland 102. As indicated above, the orifice 118 can be implemented as a single opening or multiple openings. Other variations can also be implemented.

FIG. 2 is a cross-section view diagram 200 of the metal flange 110 that cuts through the carrier gas channel 120 and premix chamber 112 for the nozzle assembly 125. The carrier gas channel 120 is fed from an external gas source, and the carrier gas can be selected based upon its compatibility with the liquid being introduced into the top of the premix chamber 112. It is also noted that for the embodiment depicted in FIGS. 1A-B, the nozzle assembly 125, including the premix chamber 112, the outlet channel 114, and the expanding nozzle 116, is constructed as an integral part of the metal flange 110. However, the nozzle assembly 125 can also be implemented as part of other structures and can also include one or more stand-alone elements. For example, a smaller nozzle assembly could be implemented from hex stock and configured to receive the metal nut 104. Other variations could also be implemented while still taking advantage of the nozzle assembly and vortical premix techniques described herein.

The carrier gas channel 120 is positioned to inject gas into the premix chamber 112 eccentrically with respect to the interior wall for the premix chamber 112. For example, the carrier gas is preferably introduced in a direction tangential to the interior wall of the premix chamber 112 to encourage strong vortical flows within the premix chamber 112. It is also noted that changes in the cross sectional area of the carrier gas channel 120 are also used to influence the speed of the vortex generated by the vortical flow within the premix chamber 112. For example, the diameter of the carrier gas channel 120 can drop down from one size within a first region 208 to a smaller size diameter within a second region 204 through a transition region 206. This reduction in diameter within the second region 204 increases the speed of the carrier gas as it enters the premix chamber 112. As one example, the premix chamber 112 and carrier gas channel 120 can be configured to generate gas flows of Argon having flow rates of about 200 SCCM (standard cubic centimeter per minute) and higher and preferably having flow rates of about 500 SCCM or higher. Other flow rates and gasses could also be used while still taking advantage of the nozzle assembly and vortical premix techniques described herein.

FIG. 3 is a representative perspective view diagram 300 for vortical flow within the premix chamber 112 and passage of the premixed liquid 308 into the outlet channel 114 and the expanding nozzle 116. The second region 204 and transition region 206 for the carrier gas channel 120 are also shown. As described above, the liquid 304 to be vaporized enters the premix chamber 112 from above through a liquid inlet 312 and is mixed with the carrier gas 306 that is introduced through a gas inlet 314. It is noted that the liquid inlet 312 can be implemented as an opening in the top of the premix chamber 112, and the gas inlet 314 can be implemented as an opening in the sidewall of the premix chamber 112. The second region 204 for the carrier gas channel 120 is coupled to the gas inlet 314. In addition as described herein, this second region 204 for the carrier gas channel 120 is positioned and oriented with respect to the premix chamber 112 so that the carrier gas 306 is introduced eccentrically to encourage vortical flow within the premix chamber 112. For example, the carrier gas 306 can be introduced in a direction tangential to the interior wall 310 of the premix chamber 112. As the liquid 304 is drawn into the vortical flow and is mixed with the carrier gas 306, the resulting premixed liquid 308 continues to be drawn into the conical region 302 at the bottom of the premix chamber 112 and ultimately exits through a bottom outlet for the premix chamber 112 into the outlet channel 114. After passing through the outlet channel 114, the premixed liquid 308 then passes through the expanding nozzle 116 that expands and further vaporizes the premixed liquid 308. The configuration and orientation of the gas channel 120 and the premix chamber 112 allow the carrier gas 306 to generate a strong vortex and a related vortical flow pattern within premix chamber 112. This vortical flow continues to influence the flow of the premixed liquid 308 as the premixed liquid 308 exits through the outlet channel 114 and the expanding nozzle 116. If desired for certain embodiments, all metal seals (e.g., VCR® and CONFLAT® fittings) can also be used to allow for high vacuum as well as high temperature with respect to the vaporizer system.

It is noted that the size of the premix chamber 112, carrier gas channel 120, orifice 118, and outlet channel 114 as well as input flows can be adjusted for the optimal operation for a given liquid, carrier gas, and semiconductor process. The following sizes provide one example embodiment for the nozzle assembly 125 and vaporizer described herein. The liquid orifice 118 can have a diameter of 0.76 mm, and this size can be easily changed by simply changing the metal gasket 108 that includes the orifice 118. The carrier gas channel 120 can have a diameter set to 0.75 mm for the second region 204 where the carrier gas is introduced into the premix chamber 112. The premix chamber 112 can have a cylindrical section with a diameter of 1.80 mm and a height of 1.6 mm before it transitions through a contracting cone provided by conical region 302 into the outlet channel 114. The outlet channel 114 can have a diameter of 0.50 mm. Variations in these sizes and diameters can be adjusted as desired based upon the particular liquid, carrier gas, and/or semiconductor process being implemented.

FIG. 4 is a cross-section diagram of an example embodiment 400 where the nozzle assembly 125 described herein is used within a full vaporizer including a vaporizer chamber 406. For the example embodiment 400, the nozzle assembly 125 is again included within the metal flange 110, which is coupled to the larger metal flange 122 using bolts 126. The metal flange 122 is in turn coupled to the top metal flange 404 for the vaporizer core 405 using bolts 128. The mounting bracket 124 is also coupled to the metal flange 122 using the bolts 128. The carrier gas channel 120 receives the carrier gas from a gas source line 402, and premixed liquid from the premix chamber within the nozzle assembly 125 is introduced into the vaporizer chamber 406 for the vaporizer core 405. As described further herein, the vaporizer chamber 406 can include additional material, such as aluminum foam, that further facilitates vaporization, and heaters can be applied to further facilitate vaporization and inhibit condensation. A bottom metal flange 408 for the vaporizer core 405 is coupled to an outlet metal flange 410 using bolts 412 to provide a metal seal at the bottom of the vaporizer core 405. The vaporized gas leaves the vaporizer chamber 406 through the gas outlet channel 414. The vaporized gas is then provided through a gas line 416 to other processing tools, for example, where the vaporized gas can be used to deposit one or more layers on a substrate within a deposition chamber for a substrate processing system.

It is noted that the orientation, length, and other configuration for the gas outlet channel 414 and related gas line 416 can be adjusted as desired. For example, rather than extending laterally as shown, the gas outlet channel 414 may be oriented such that it extends vertically towards a deposition chamber located below the vaporizer core 405. In addition, the gas outlet 414 and gas line 416 can extend to one or more additional processing tools located at various distances from the vaporizer. While these distances are preferably short, the distances can include distances of up to 15 feet or more depending upon the chemistry and processes involved. Although not shown, it is also noted that heaters can be positioned around the perimeter of each component within the vaporizer, including the vaporizer core 405, to facilitate vaporization and to inhibit or prevent condensation. Further, heaters can also be positioned around the gas outlet 414 and gas line 416 to inhibit or prevent condensation. In addition, the housing for the vaporizer chamber 406 can be aluminum to facilitate heat transfer to aluminum foam within the vaporizer chamber 406. Further, the top metal flange 404 and the bottom metal flange 408 can be implemented using bimetal metal flanges including stainless steel sealing faces explosion welded to an aluminum body, which are available from Atlas Technologies. The aluminum bodies for these bimetal metal flanges then allow for better heat transfer to the aluminum housing for the vaporizer chamber 406 in such embodiments. Other variations can also be implemented while still taking advantage of the nozzle assembly and vortical premix techniques described herein.

It is noted that the overall operation of the vaporizer can be implemented similarly to the operation described within U.S. Pat. No. 9,523,151, which is hereby incorporated by reference in its entirety. For example, as described in U.S. Pat. No. 9,523,151 open cell aluminum foam can be used within the vaporizer chamber 406. This foam can be vacuum brazed to a heated aluminum housing for the vaporizer chamber 406 thereby providing excellent thermal communication between the aluminum foam and the aluminum wall of the vaporizer chamber 406. An aluminum braze can also be used instead of a more volatile braze material that may contaminate the chemistry of the overall process. In effect, the open cell aluminum foam greatly diminishes the distance from the heated wall of the vaporizer chamber 406 to the evaporating droplets passing through the vaporizer chamber 406.

In operation, as the droplets evaporate within the vaporizer chamber 406, their temperature can decrease considerably. For certain embodiments, additional energy is provided through heaters to maintain the evaporation process and rate. Because the vaporizing environment is a vacuum, thermal conduction to the heated wall through the gas is limited. As such, prior vaporizers that have open vaporization chambers typically operate at temperature much higher than optimal in order to create a temperature gradient high enough to overcome the thermal resistance of the rarified gas within the open vaporization chamber. For such open chamber systems, droplets that fail to fully vaporize and travel through the chamber intact can land on the surface of the wall, which in its overheated state not only induces flash vaporization but also induces potential chemical breakdown. This chemical breakdown can produce deposits, particles, and other unwanted byproducts within the system. However, if a lower temperature is employed in such open chamber systems, non-vaporized droplets can pool, and these pooled chemicals can potentially affect the stability of supply lines to the process chamber and/or chemically break down thereby adversely impacting the system. The utilization of heated aluminum foam within the vaporizer chamber 406 as described in U.S. Pat. No. 9,523,151, however, reduces the thermal resistance between the droplets and the heated wall by reducing the distance between them. This reduction in thermal resistance permits the use of a much lower operating temperature for the vaporizer system, encouraging vaporization without direct wall contact.

FIG. 5 is a process diagram of an example embodiment 500 for using a nozzle assembly as described herein for vaporization within a substrate processing system. In block 502, a substrate processing system is operated that includes a vaporization chamber and a nozzle assembly including a premix chamber, an outlet channel, and an expanding nozzle. Process flow then passes to both blocks 504 and 506. In block 504, a liquid is introduced into the premix chamber for the nozzle assembly. In block 506, a carrier gas is introduced into the premix chamber to generate a vortical flow within the premix chamber as described herein. Process flow then passes to block 508 where the premixed liquid from the premix chamber is passed through an outlet channel and an expanding nozzle for the nozzle assembly to facilitate vaporization of the premixed liquid. In addition, as described above, the outlet channel is configured to generate backpressure within the premix chamber that facilitates operation and performance of the vaporizer system. Process flow then passes to block 510 where the resulting premixed liquid from the expanding nozzle is received within the vaporization chamber. As also described herein, the vaporization chamber can include heated aluminum foam or other materials that further facilitate vaporization of the premixed liquid prior to its being deposited on a substrate within the vaporization chamber. Variations as well as different and/or additional process steps can also be implemented while still taking advantage of the nozzle assembly and vortical premix techniques described herein.

It is noted that the term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

It is further noted that the nozzle assembly and related vaporizer described herein can be used for the deposition systems described within U.S. Pat. No. 9,523,151, which again is hereby incorporated by reference in its entirety. In part, U.S. Pat. No. 9,523,151 describes methods and system including a nozzle assembly that are used to vaporize a liquid-phase precursor for use in deposition of one or more material layers on a substrate.

FIG. 6 illustrates a substrate processing system 600 that is also described in U.S. Pat. No. 9,523,151 and that uses a vaporizer 40 to deposit a thin film, such as a conductive film, a non-conductive film, or a semi-conductive film. The vaporizer 40 can include the nozzle assembly described above including the premix chamber 112, the outlet channel 114, the expanding nozzle 116, and the carrier gas channel 120.

For the example substrate processing system 600, the thin film can include a dielectric film, such as a low dielectric constant (low-k) or ultra-low-k dielectric film, or the thin film may include a sacrificial layer for use in air gap dielectrics. Substrate processing system 600 can include a chemical vapor deposition (CVD) system, whereby a film forming composition is thermally activated or decomposed in order to form a film on a substrate. Alternatively, deposition 600 can include a plasma enhanced chemical vapor deposition (PECVD) system, whereby a film forming composition is activated or decomposed with assistance by plasma in order to form a film on a substrate. Alternatively yet, the substrate processing system 600 can include a pyrolytic CVD system, whereby a film forming composition is activated or decomposed when interacting with a heating element in order to form a film on a substrate. And, while additional details are provided below for a CVD system, the vaporizer to be described may be used in any substrate processing system requiring vaporization of a liquid phase material, including an atomic layer deposition (ALD) system. The vaporizer in this invention can be used in vapor-phase processing in semiconductors, flat panel displays, and solar panel processing. In the area of vapor deposition systems, the vaporizer can be used in thermal CVD systems including pyrolytic CVD, plasma enhanced CVD, atomic layer deposition (ALD), and plasma enhanced ALD systems.

The substrate processing system 600 comprises a process chamber 10 having a substrate holder 20 configured to support a substrate 25, upon which the thin film is formed. Furthermore, the substrate holder 20 is configured to control the temperature of the substrate 25 at a temperature suitable for the film forming reactions.

The process chamber 10 is coupled to a film forming composition delivery system 30 configured to introduce a film forming composition to the process chamber 10 through a vaporizer 40. Furthermore, the vaporizer 40 includes a vaporizer chamber 45 having an inlet end coupled to an output from the film forming composition delivery system 30 and an outlet end coupled to the process chamber 10 through an optional gas distribution device. The vaporizer chamber 45 comprises one or more heating elements 55 disposed therein, and a power source 50 that is coupled to the one or more heating elements 55 and that is configured to deliver electrical power to the one or more heating elements 55. For example, the one or more heating elements 55 can comprise one or more conductively heated porous elements.

The process chamber 10 is further coupled to a vacuum pumping system 60 through a duct 62, wherein the vacuum pumping system 60 is configured to evacuate the process chamber 10 to a pressure suitable for forming the thin film on the substrate 25.

The film forming composition delivery system 30 can include one or more material sources configured to introduce a film forming composition to the vaporizer 40. For example, the film forming composition may include one or more gases, or one or more vapors formed in one or more gases, or a mixture of two or more thereof. The film forming composition delivery system 30 can include one or more gas sources, or one or more liquid sources, or a combination thereof. Herein vaporization refers to the transformation of a material (normally stored in a state other than a gaseous state) from a non-gaseous state to a gaseous or vapor state. Therefore, the terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas.

When the film forming composition is introduced to the vaporizer system 40, one or more constituents of the film forming composition are subjected to vaporization in the vaporization chamber 45 described above. The film forming composition can include film precursors that facilitate film formation on substrate 25 in the process chamber 10. The film precursor or precursors may include the principal atomic or molecular species of the film desired to be produced on the substrate. Additionally, the film forming composition can include a reducing agent. The reducing agent or agents may assist with the reduction of a film precursor on substrate 25. For instance, the reducing agent or agents may react with a part of or all of the film precursor on substrate 25. Additionally yet, the film forming composition can include a polymerizing agent (or cross-linker). The polymerizing agent may assist with the polymerization of a film precursor or fragmented film precursor on substrate 25.

According to one embodiment, when forming a copolymer thin film on substrate 25, a film forming composition comprising two or more monomers is introduced to the process chamber 10 in vapor-phase. These monomers are introduced to and distributed within process space 33 in the vicinity of the upper surface of substrate 25. Substrate 25 is maintained at a temperature lower than that of the vaporizer chamber 45 in order to condensate and induce polymerization of the chemically altered film forming composition at the upper surface of substrate 25.

For example, when forming an organosilicon polymer, monomer gas or gases of an organosilicon precursor is used. Additionally, for example, when forming a fluorocarbon-organosilicon copolymer, monomer gases of a fluorocarbon precursor and organosilicon precursor are used.

Further yet, the film forming composition can include an initiator. An initiator or fragmented initiator may assist with the fragmentation of a film precursor, or the polymerization of a film precursor. The use of an initiator can permit higher deposition rates at lower heat source temperatures. For instance, the one or more heating elements can be used to fragment the initiator to produce radical species of the initiator (i.e., a fragmented initiator) that are reactive with one or more of the remaining constituents in the film forming composition. Furthermore, for instance, the fragmented initiator or initiator radicals can catalyze the formation of radicals of the film forming composition.

For example, when forming a fluorocarbon-organosilicon copolymer, the initiator can be perfluorooctane sulfonyl fluoride (PFOSF) used in the polymerization of a cyclic vinylmethylsiloxane, such as 1,3,5-trivinyl-1,3,5-trimethylcyclotrisiloxane (V₃D₃).

Additionally, for example, when forming a porous SiCOH-containing film, the film forming composition may comprise a structure-forming material and a pore-generating material. The structure-forming material may comprise diethoxymethylsilane (DEMS) and the pore-generating material may comprise alpha-terpinene (ATRP). The porous SiCOH-containing film may be used as a low dielectric constant (low-k) material.

Further, for example, when forming a cross-linked neopentyl methacrylate organic glass, the film forming composition may comprise a monomer, a cross-linker, and an initiator. The monomer may comprise trimethylsilylmethyl methacrylate (TMMA), propargyl methacrylate (PMA), cyclopentyl methacrylate ((CDMA), neopentyl methacrylate (npMA), and poly (neopentyl methacrylate) (P(npMA)), and the cross-linker may comprise ethylene glycol diacrylate (EGDA), ethylene glycol dimethacrylate (EGDMA), 1,3-propanediol diacrylate (PDDR), or 1,3-propanediol dimethacrylate (PDDMA), or any combination of two or more thereof. Additionally, the initiator may comprise a peroxide, a hydroperoxide, or a diazine. Additionally yet, the initiator may comprise a tort-butyl peroxide (TBPO).

Further yet, for example, the polymer film may comprise P(npMA-co-EGDA) (poly(neopentyl methacrylate-co-ethylene glycol diacrylate)), and the monomer comprises npMA (neopentyl methacrylate) and the cross-linker comprises EGDA (ethylene glycol diacrylate). The polymer film may be used as a sacrificial air gap material.

According to one embodiment, the film forming composition delivery system 30 can include a first material source 32 configured to introduce one or more film precursors to the vaporizer 40, and a second material source 34 configured to introduce a (chemical) initiator to the vaporizer 40. Furthermore, the film forming gas delivery system 30 can include additional gas sources configured to introduce an inert gas, a carrier gas or a dilution gas. For example, the inert gas, carrier gas or dilution gas can include a noble gas, i.e., He, Ne, Ar, Kr, Xe, or Rn.

According to another embodiment, the film forming composition delivery system 30 can include a first material source 32 configured to introduce one or more film precursors to the vaporizer 40, a second material source 34 configured to introduce a (chemical) initiator to the vaporizer 40, and/or a third material source 36 configured to introduce a vapor-phase precursor to the vaporizer 40. The third material source 36 can be a vaporizer comprising a vaporizer chamber and at least one porous foam member arranged within said vaporizer. Device details of the vaporizer are discussed in subsequent figures. Furthermore, the film forming gas delivery system 30 can include additional gas sources configured to introduce an inert gas, a carrier gas or a dilution gas. For example, the inert gas, carrier gas or dilution gas can include a noble gas, i.e., He, Ne, Ar, Kr, Xe, or Rn.

Referring again to FIG. 6, the power source 50 is configured to provide an electrical power to the one or more heating elements 55 in the vaporizer 40. For example, the power source 50 can be configured to deliver either DC power or AC power. Additionally, for example, the power source 50 can be configured to modulate the amplitude of the power, or pulse the power. Furthermore, for example, the power source 50 can be configured to perform at least one of setting, monitoring, adjusting or controlling a power, a voltage, or a current. In another embodiment, an optional plasma generator 52 can be coupled to the process chamber 10 for a plasma enhanced CVD processing of the substrate 25.

Referring still to FIG. 6, a temperature control system 22 can be coupled to the vaporizer 40, the vaporizer chamber 45, the process chamber 10 and/or the substrate holder 20, and configured to control the temperature of one or more of these components. The temperature control system 22 can include a temperature measurement system configured to measure the temperature of the vaporizer 40 at one or more locations, the temperature of the vaporizer chamber 45 at one or more locations, the temperature of the process chamber 10 at one or more locations and/or the temperature of the substrate holder 20 at one or more locations. The measurements of temperature can be used to adjust or control the temperature at one or more locations in substrate processing system 600.

The temperature measuring device, utilized by the temperature measurement system, can include an optical fiber thermometer, an optical pyrometer, a band-edge temperature measurement system, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg., Model No. FT-1420.

Alternatively, when measuring the temperature of one or more resistive heating elements, the electrical characteristics of each resistive heating element can be measured. For example, two or more of the voltage, current or power coupled to the one or more resistive heating elements can be monitored in order to measure the resistance of each resistive heating element. The variations of the element resistance can arise due to variations in temperature of the element which affects the element resistivity.

According to program instructions from the temperature control system 22 or the controller 80 or both, the power source 50 can be configured to operate the vaporizer chamber 45, e.g., the one or more porous gas distribution elements, at a temperature ranging from approximately 100 degrees C. to approximately 600 degrees C. For example, the temperature can range from approximately 200 degrees C. to approximately 550 degrees C. The temperature can be selected based upon the film forming composition and, more particularly, the temperature can be selected based upon a constituent of the film forming composition.

Additionally, according to program instructions from the temperature control system 22 or the controller 80 or both, the temperature of the vaporizer 40 can be set to a value approximately equal to or less than the temperature of the vaporizer chamber 45, i.e., the one or more heating elements. For example, the temperature can be a value less than or equal to approximately 600 degrees C. Additionally, for example, the temperature can be a value less than approximately 550 degrees C. Further yet, for example, the temperature can range from approximately 80 degrees C. to approximately 550 degrees C. The temperature can be selected to be approximately equal to or less than the temperature of the one or more heating elements, and to be sufficiently high to prevent condensation which may or may not cause film formation on surfaces of the gas distribution system and reduce the accumulation of residue.

Additionally yet, according to program instructions from the temperature control system 22 or the controller 80 or both, the temperature of the process chamber 10 can be set to a value less than the temperature of the vaporizer chamber 45, i.e., the one or more heating elements. For example, the temperature can be a value less than approximately 200 degrees C. Additionally, for example, the temperature can be a value less than approximately 150 degrees C. Further yet, for example, the temperature can range from approximately 80 degrees C. to approximately 150 degrees C. However, the temperature may be the same or less than the temperature of the vaporizer 40. The temperature can be selected to be less than the temperature of the one or more resistive film heating elements, and to be sufficiently high to prevent condensation which may or may not cause film formation on surfaces of the process chamber and reduce the accumulation of residue.

Once film forming composition enters the process space 33, the film forming composition adsorbs on the substrate surface, and film forming reactions proceed to produce a thin film on the substrate 25. According to program instructions from the temperature control system 22 or the controller 80 or both, the substrate holder 20 is configured to set the temperature of substrate 25 to a value less than the temperature of the vaporizer chamber 45, the temperature of the vaporizer 40, and the process chamber 10. For example, the substrate temperature can range up to approximately 80 degrees C. Additionally, the substrate temperature can be approximately room temperature. For example, the substrate temperature can range up to approximately 25 degrees C. However, the temperature may be less than or greater than room temperature.

The substrate holder 20 comprises one or more temperature control elements coupled to the temperature control system 22. The temperature control system 22 can include a substrate heating system, or a substrate cooling system, or both. For example, substrate holder 20 can include a substrate heating element or substrate cooling element (not shown) beneath the surface of the substrate holder 20. For instance, the heating system or cooling system can include a re-circulating fluid flow that receives heat from substrate holder 20 and transfers heat to a heat exchanger system (not shown) when cooling, or transfers heat from the heat exchanger system to the substrate holder 20 when heating. The cooling system or heating system may include heating/cooling elements, such as resistive heating elements, or thermo-electric heaters/coolers located within substrate holder 20. Additionally, the heating elements or cooling elements or both can be arranged in more than one separately controlled temperature zone. The substrate holder 20 may have two thermal zones, including an inner zone and an outer zone. The temperatures of the zones may be controlled by heating or cooling the substrate holder thermal zones separately.

Additionally, the substrate holder 20 comprises a substrate clamping system (e.g., electrical or mechanical clamping system) to clamp the substrate 25 to the upper surface of substrate holder 20. For example, substrate holder 20 may include an electrostatic chuck (ESC).

Furthermore, the substrate holder 20 can facilitate the delivery of heat transfer gas to the back-side of substrate 25 via a backside gas supply system to improve the gas-gap thermal conductance between substrate 25 and substrate holder 20. Such a system can be utilized when temperature control of the substrate is required at elevated or reduced temperatures. For example, the backside gas system can comprise a two-zone gas distribution system, wherein the backside gas (e.g., helium) pressure can be independently varied between the center and the edge of substrate 25.

Vacuum pumping system 60 can include a turbo-molecular vacuum pump (TMP) capable of a pumping speed up to approximately 5000 liters per second (and greater) and a gate valve for throttling the chamber pressure. For example, a 1000 to 3000 liter per second TMP can be employed. TMPs can be used for low pressure processing, typically less than approximately 1 Torr. For high pressure processing (i.e., greater than approximately 1 Torr), a mechanical booster pump and dry roughing pump can be used. Furthermore, a device for monitoring chamber pressure (not shown) can be coupled to the process chamber 10. The pressure measuring device can be, for example, a Type 628B Baratron absolute capacitance manometer commercially available from MKS Instruments, Inc. (Andover, Mass.).

Referring still to FIG. 6, the substrate processing system 600 can further comprise a controller 80 that comprises a microprocessor, memory, and a digital I/O port capable of generating control voltages sufficient to communicate and activate inputs to substrate processing system 600 as well as monitor outputs from substrate processing system 600. Moreover, controller 80 can be coupled to and can exchange information with the process chamber 10 the substrate holder 20, the temperature control system 22, the film forming delivery system 30, the vaporizer system 40, the vaporizer chamber 45, and the vacuum pumping system 60, as well as the backside gas delivery system (not shown), and/or the electrostatic clamping system (not shown). A program stored in the memory can be utilized to activate the inputs to the aforementioned components of substrate processing system 600 according to a process recipe in order to perform the method of depositing a thin film.

Controller 80 may be locally located relative to the substrate processing system 600, or it may be remotely located relative to the substrate processing system 600 via an internet or intranet. Thus, controller 80 can exchange data with the substrate processing system 600 using at least one of a direct connection, an intranet, or the internet. Controller 80 may be coupled to an intranet at a customer site (i.e., a device maker, etc.), or coupled to an intranet at a vendor site (i.e., an equipment manufacturer). Furthermore, another computer (i.e., controller, server, etc.) can access controller 80 to exchange data via at least one of a direct connection, an intranet, or the internet.

The substrate processing system 600 can be periodically cleaned using an in-situ cleaning system (not shown) coupled to, for example, the process chamber 10 or the vaporizer 40. Per a frequency determined by the operator, the in-situ cleaning system can perform routine cleanings of the substrate processing system 600 in order to remove accumulated residue on internal surfaces of substrate processing system 600. The in-situ cleaning system can, for example, comprise a radical generator configured to introduce chemical radical capable of chemically reacting and removing such residue. Additionally, for example, the in-situ cleaning system can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), O₃, XeF₂, ClF₃, or C₃F₈ (or, more generally, CₓF_{y}), respectively. The radical generator can include an ASTRON® reactive gas generator, commercially available from MKS Instruments, Inc., ASTeX® Products (90 Industrial Way, Wilmington, Mass. 01887).

Although the porous gas distribution device has been described for use in a substrate processing system such as a deposition system, the porous gas distribution device and vaporizer may be used in any system requiring gas heating and vaporization of a liquid-phase material. Other such systems in semiconductor manufacturing and integrated circuit (IC) manufacturing may include etching systems, plasma-enhanced etch systems, thermal processing systems, and the like.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A vaporizer to introduce a vaporized liquid into a substrate processing system, comprising:
a vaporizer chamber having an inlet;
a nozzle assembly coupled to the inlet for the vaporizer chamber, comprising:
a premix chamber having a liquid inlet to receive a liquid to be vaporized and a gas inlet to receive a carrier gas;
an outlet channel to receive a premixed liquid from the premix chamber, and
an expanding nozzle coupled to the outlet channel; and
a carrier gas channel coupled to the gas inlet for the premix chamber and positioned with respect to the gas inlet to cause a vortical flow within the premix chamber upon introduction of the carrier gas through the carrier gas channel.

2. The vaporizer of claim 1, wherein the premix chamber comprises a cylindrical region including the liquid inlet and a conical region adjacent the outlet channel.

3. The vaporizer of claim 2, wherein the conical region comprises a contracting cone configured to increase a speed for the premixed liquid leaving the premix chamber.

4. The vaporizer of claim 1, wherein the expanding nozzle comprises an expanding cone configured to facilitate vaporization of the premixed liquid.

5. The vaporizer of claim 1, wherein the carrier gas channel is positioned to introduce the carrier gas into the premix chamber in a direction tangential to the interior wall of the premix chamber.

6. The vaporizer of claim 5, wherein the carrier gas channel has multiple regions with different diameters including a first region coupled to a source for the carrier gas and a second region coupled to the gas inlet for the premix chamber, the second region having a smaller diameter than the first region.

7. The vaporizer of claim 1, further comprising a metal fitting positioned to introduce the liquid through the liquid inlet for the premix chamber.

8. The vaporizer of claim 7, further comprising a metal gasket within the metal fitting, the metal gasket having an orifice configured to introduce the liquid through the liquid inlet for the premix chamber.

9. The vaporizer of claim 8, wherein the metal fitting comprises a receptacle having one or more access ports configured to allow the metal gasket to be accessed and removed.

10. The vaporizer of claim 8, wherein the nozzle assembly is formed as part of a metal flange coupled to the metal fitting.

11. The vaporizer of claim 10, further comprising a threaded receptacle welded to the metal flange, the threaded receptacle being configured to receive a metal nut for the metal fitting.

12. The vaporizer of claim 11, wherein the metal fitting, the metal flange, and the threaded receptacle provide metal-to-metal vacuum seals.

13. The vaporizer of claim 1, wherein the outlet channel is sized to generate backpressure within the premix chamber.

14. The vaporizer of claim 13, wherein the backpressure is configured to reduce early vaporization within the premix chamber and to reduce residue build-up within the liquid inlet and the gas inlet.

15. The vaporizer of claim 1, wherein the nozzle assembly is configured to achieve a target residence time for the liquid within the premix chamber prior.

16. The vaporizer of claim 15, wherein the target residence time is configured to reduce early vaporization within the premix chamber and to reduce residue build-up within the liquid inlet and the gas inlet.

17. The vaporizer of claim 1, wherein the vortical flow is configured to cause a sweeping action for the carrier gas within the premix chamber.

18. The vaporizer of claim 17, wherein the sweeping action is configured to reduce residue build-up within the premix chamber.

19. The vaporizer of claim 1, further comprising at least one porous foam member arranged within the vaporizer chamber between the inlet for the vaporizer chamber and an outlet for the vaporizer chamber.

20. The vaporizer of claim 19, wherein the at least one porous foam member comprises an aluminum foam.

21. A method to introduce a vaporized liquid into a substrate processing system using a vaporizer chamber and a nozzle assembly coupled to the vaporizer chamber, comprising:
introducing a liquid into a premix chamber for the nozzle assembly through a liquid inlet for the premix chamber, the nozzle assembly also comprising an outlet channel coupled to the premix chamber and an expanding nozzle coupled to the outlet channel;
while introducing the liquid into the premix chamber, also introducing a carrier gas into the premix chamber through a gas inlet for the premix chamber to generate a premixed liquid;
passing the premixed liquid from the premix chamber through the outlet channel and the expanding nozzle to facilitate vaporization of the premixed liquid; and
injecting the premixed liquid from expanding nozzle into the vaporizer chamber through an inlet for the vaporizer chamber;
wherein the carrier gas is introduced through the gas inlet for the premix chamber using a carrier gas channel positioned with respect to the gas inlet for the premix chamber to cause a vortical flow within the premix chamber.

22. The method of claim 21, wherein the premix chamber comprises a cylindrical region including the liquid inlet and a conical region adjacent the outlet channel.

23. The method of claim 22, wherein a speed of the premixed liquid is increased by a contracting cone within the conical region as the premixed liquid flows into the outlet channel.

24. The method of claim 21, facilitating vaporization of the premixed liquid using an expanding cone for the expanding nozzle.

25. The method of claim 21, further comprising introducing the carrier gas into the premix chamber in a direction tangential to an interior wall of the premix chamber.
